(19) United States
(12) Patent Application Publication
(10) Pub. No.: US 2026/0122828 A1
(43) Pub. Date: Apr. 30, 2026

(54) Information Handling System Connector Adapter System

(71) Applicant: Dell Products L.P., Round Rock, TX (US)

(72) Inventors: Hsiang-Yin Hung, Taipei (TW); Sean O'Donnell, Poughkeepsie, NY (US); Hsu-Chu Wang, Taipei City (TW)

(21) Appl. No.: 18/926,417

(22) Filed: Oct. 25, 2024

(51) Int. Cl. H05K 7/14

(52) U.S. Cl. CPC H05K 7/1491

(57) ABSTRACT

A connector adapter system of an information handling system. The connector adapter system includes a connector adapter, the connector adapter comprising an adapter chassis, the adapter chassis being configured to slidably mount a cable connector within the adapter chassis, the adapter chassis facilitating connection of the cable connector with an internally mounted component of the information handling system.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

In one embodiment, the invention relates to a connector adapter component of a connector adapter system of an information handling system, comprising: an adapter chassis, the adapter chassis being configured to slidably mount a cable connector within the adapter chassis, the adapter chassis facilitating connection of the cable connector with an internally mounted component of the information handling system.

In another embodiment, the invention relates to a connector adapter system of an information handling system, comprising: a connector adapter, the connector adapter comprising an adapter chassis, the adapter chassis being configured to slidably mount a cable connector within the adapter chassis, the adapter chassis facilitating connection of the cable connector with an internally mounted component of the information handling system.

In another embodiment, the invention relates to a server type information handling system comprising: a processor; a data bus coupled to the processor; a chassis, an internally mounted component mounted within the chassis; and, a connector adapter system, the connector adapter system comprising a connector adapter, the connector adapter comprising an adapter chassis, the adapter chassis being configured to slidably mount a cable connector within the adapter chassis, the adapter chassis facilitating connection of the cable connector with the internally mounted component of the information handling system.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a generalized perspective view of an example rack server type information handling system.

FIGS. 3A and 3B, generally referred to as FIG. 3, show views of a connector adapter component of a connector adapter system.

FIGS. 4A, 4B, 4C and 4D, generally referred to as FIG. 4, show views of a guiding structure of a connector adapter system.

FIGS. 5A, 5B, 5C and 5D, generally referred to as FIG. 5, show side views of the operation of a connector adapter component of a connector adapter system.

FIGS. 6A, 6B and 6C, generally referred to as FIG. 6, show operational views of assembly of a connector adapter component of a connector adapter system.

FIGS. 7A, 7B, 7C, 7D and 7E, generally referred to as FIG. 7, show operational views of a guide structure of a connector adapter system.

FIGS. 8A and 8B, generally referred to as FIG. 8, show operational side views of a connector adapter system.

### DETAILED DESCRIPTION

Various aspects of the disclosure include an appreciation that it is known to provide a graphics processing unit in an information handling system such as a server type information handling system. Various aspects of the present disclosure include an appreciation that it is known to provide information handling systems with a graphic processing unit which communicates via an active optical cable. Various aspects of the present disclosure include an appreciation that certain known graphics processing units include an octal small form factor pluggable (OSFP) connector via which the active optical cable is coupled with the graphics processing unit.

Various aspects of the present disclosure include an appreciation that certain known information handling systems install a graphics processing unit module in an interior location within the information handling system chassis. Various aspects of the present disclosure include an appreciation that such an installation location can present certain access challenges. Various aspects of the present disclosure include an appreciation that such a graphics processing unit module installation location can result in a rear fan module restricting external access to the graphics processing unit module. Various aspects of the present disclosure include an appreciation that such a graphics processing unit module installation location can present challenges relating to plugging and unplugging graphics processing unit cables such as an OSFP type cable.

Various aspects of the present disclosure include an appreciation that when a graphics processing unit module is installed in an interior location within the information handling system chassis a connector would need to travel a depth inward to reach the graphics processing unit module. Various aspects of the present disclosure include an appreciation that when a graphics processing unit module is installed in an interior location within the information handling system chassis this depth can be substantially 141.85 mm. Various aspects of the present disclosure include an appreciation that when a graphics processing unit module is installed in an interior location within the information handling system chassis a Y-axis opening under fan module cage can be limited. Various aspects of the present disclosure include an appreciation that when a graphics processing unit module is installed in an interior location within the information handling system chassis a Y-axis opening under fan module cage can be substantially 39 mm. Various aspects of the present disclosure include an appreciation that with a limited Y-axis opening it can be challenging to hold and install the connector to the graphics processing unit module.

Various aspects of the present disclosure include an appreciation that when a graphics processing unit module is installed in an interior location within the information handling system chassis when the cable is installed in the chassis, a cable pull ring is often invisible and unreachable from outside of chassis. Various aspects of the present disclosure include an appreciation that when a graphics processing unit module is installed in an interior location within the information handling system chassis it can be challenging to release a cable connector that is installed on the graphics processing unit module. Various aspects of the present disclosure include an appreciation that when a graphics processing unit module is installed in an interior location within the information handling system chassis unless a fan module cage is removed it can be challenging to install and remove cables with the graphics processing unit module.

Various aspects of the present disclosure include an appreciation that it would be desirable to provide a connector adapter box to facilitate graphics processing unit cable installation and removal. Various aspects of the present disclosure include an appreciation that it would be desirable to provide a connector adapter box with an extended release function to facilitate graphics processing unit cable installation and removal.

A system and method are disclosed for providing a graphics processing unit module with a connector adapter system. In certain embodiments, the connector adapter system facilitates graphics processing unit cable installation and removal. In certain embodiments, the connector adapter system includes an extended release function to facilitate graphics processing unit cable installation and removal. In certain embodiments, the graphics processing unit cable includes an OSFP type cable connector.

In certain embodiments, the connector adapter system includes a connector adapter component. In certain embodiments, the connector adapter component includes an adapter chassis. In certain embodiments, the adapter chassis includes a top cover and a bottom cover. In certain embodiments, the adapter chassis includes a top cover and a bottom cover. In certain embodiments, the top cover includes a release latch and a spring component. In certain embodiments, the release latch is used to separate the top and bottom covers. In certain embodiments, the spring component attached to the top cover provides a constraint to OSFP cable connectors of various shapes. In certain embodiments, the bottom cover holds the OSFP connector in place.

In certain embodiments, the connector adapter system includes a strap portion. In certain embodiments, the strap portion wraps around a pull ring of the connector. In certain embodiments, the strap portion includes a loop and hook fastener. In certain embodiments, the loop and hook fastener includes a Velcro type fastener. In certain embodiments, the strap portion provides an extended release mechanism for disconnecting the connector from the graphics processing unit.

In certain embodiments, the connector adapter system includes a guiding structure. In certain embodiments, the guiding structure of the connector adapter system is positioned on a chassis side location. In certain embodiments, the guiding structure constrains movements of the cable plug during installation of the cable plug.

Providing a connector adapter system with an extending release mechanism advantageously facilitates the installation and removal of OSFP connectors in situations where access to the connectors is challenging. In certain embodiments, the cable system adapter chassis extends the operational area of the connector, thereby allowing the connector to reach a graphics processing unit installed within an interior of an information handling system chassis. In certain embodiments, the connector adapter system extended release mechanism which is wrapped around a connector pull ring allows the connector assembly to be easily removed from the graphics processing unit.

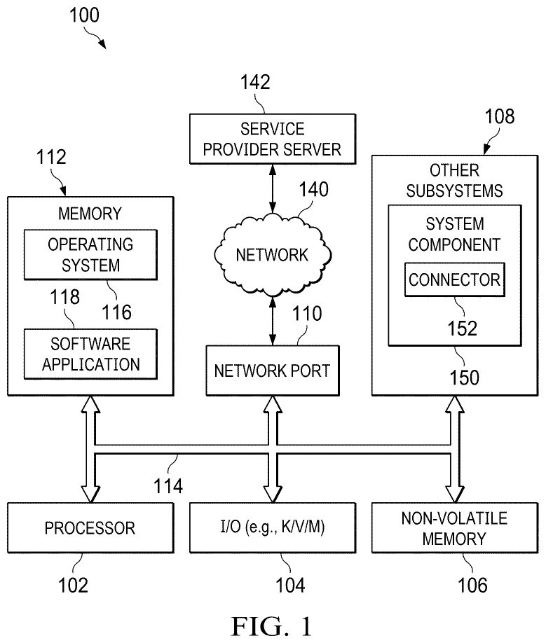

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a rack server type information handling system. As used herein, a rack server type information handling system broadly refers to an information handling system which is physically configured to be mounted within a server rack.

In certain embodiments, the information handling system 100 includes a graphics processing unit (GPU) module 150. In certain embodiments, the graphics processing unit module 150 includes a GPU connector 152. In certain embodiments, the GPU connector 152 includes an octal small form factor pluggable (OSFP) type connector.

In certain embodiments, the GPU connector 152 includes a connector adapter system. In certain embodiments, the connector adapter system facilitates graphics processing unit cable installation and removal. In certain embodiments, the connector adapter system includes an extended release function to facilitate graphics processing unit cable installation and removal. In certain embodiments, the graphics processing unit cable includes an OSFP type cable connector.

In certain embodiments, the connector adapter system includes a connector adapter component. In certain embodiments, the connector adapter component includes an adapter chassis. In certain embodiments, the adapter chassis includes a top cover and a bottom cover. In certain embodiments, the top cover includes a release latch and a spring component. In certain embodiments, the release latch is used to separate the top and bottom covers. In certain embodiments, the spring component attached to the top cover provides a constraint to OSFP cable connectors of various shapes. In certain embodiments, the bottom cover holds the OSFP connector in place.

In certain embodiments, the connector adapter system includes a strap portion. In certain embodiments, the strap portion wraps around a pull ring of the connector. In certain embodiments, the strap portion includes a loop and hook fastener. In certain embodiments, the loop and hook fastener includes a Velcro type fastener. In certain embodiments, the strap portion provides an extended release mechanism for disconnecting the connector from the graphics processing unit.

In certain embodiments, the connector adapter system includes a guiding structure. In certain embodiments, the guiding structure of the connector adapter system is positioned on a chassis side location. In certain embodiments, the guiding structure constrains movements of the cable plug during installation of the cable plug.

Providing a connector adapter system with an extending release mechanism advantageously facilitates the installation and removal of OSFP connectors in situations where access to the connectors is challenging. In certain embodiments, the cable system adapter chassis extends the operational area of the connector, thereby allowing the connector to reach a graphics processing unit installed within an interior of an information handling system chassis. In certain embodiments, the connector adapter system extended release mechanism which is wrapped around a connector pull ring allows the connector assembly to be easily removed from the graphics processing unit.

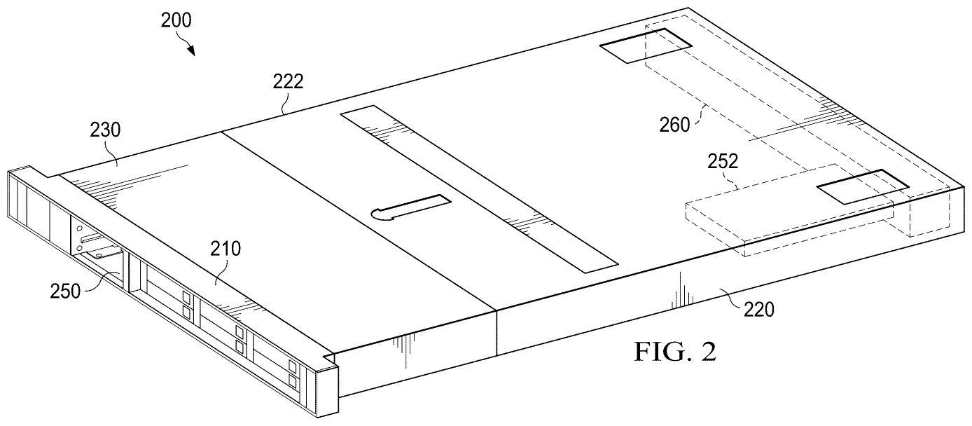

FIG. 2 shows a generalized perspective view of an example rack server type information handling system 200. In certain embodiments, the rack server type information handling system includes a front portion 210, which is accessible when the rack server type information handing system 200 is mounted on a server rack. In certain embodiments, the side portions 220, 222 mount to the rack via respective server mounting components. In certain embodiments, the side portions mount to the rack via respective mechanical guiding features which are mechanically coupled to respective server mounting components. In certain embodiments, the rack server type information handling system can slide out from the rack via the respective mechanical guiding features. In certain embodiments, the rack type information handing system 200 includes a bay 250 via which components may be mounted to the rack type information handling system.

In certain embodiments, the information handling system 200 may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit and a 4U rack unit. In general, a 1U rack unit is substantially (i.e., +/−20%) 1.75″ high, a 2U rack unit is substantially (i.e., +/−20%) 3.5″ high and a 4U rack height is substantially (i.e., +/−20%) 7.0″ high. In certain embodiments, the plurality of service sizes includes open rack (OU) server sizes. As used herein, an open rack server size broadly refers to a standardized server system height conforming to an OpenRack standard.

In certain embodiments, the information handling system 200 includes an internally mounted component 250, a fan system 252, or a combination thereof. In certain embodiments, the internally mounted component 250 includes a graphics processing unit module. As used herein, an internally mounted component broadly refers to a component which is mounted within an information handling system chassis such that edges of the component are not contiguous with either a front or a rear wall of the information handling system chassis. In certain embodiments, another component may be located between edges of the component and either the front or rear wall of the information handling system chassis. For example, in certain embodiments, the fan system 352 is positioned between the internally mounted component 250 and the rear wall of the information handling system chassis.

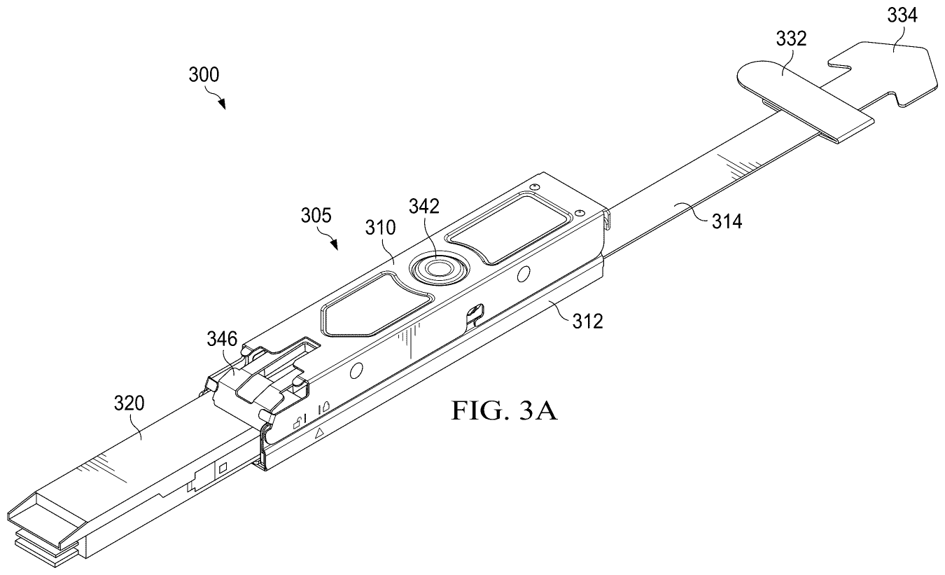

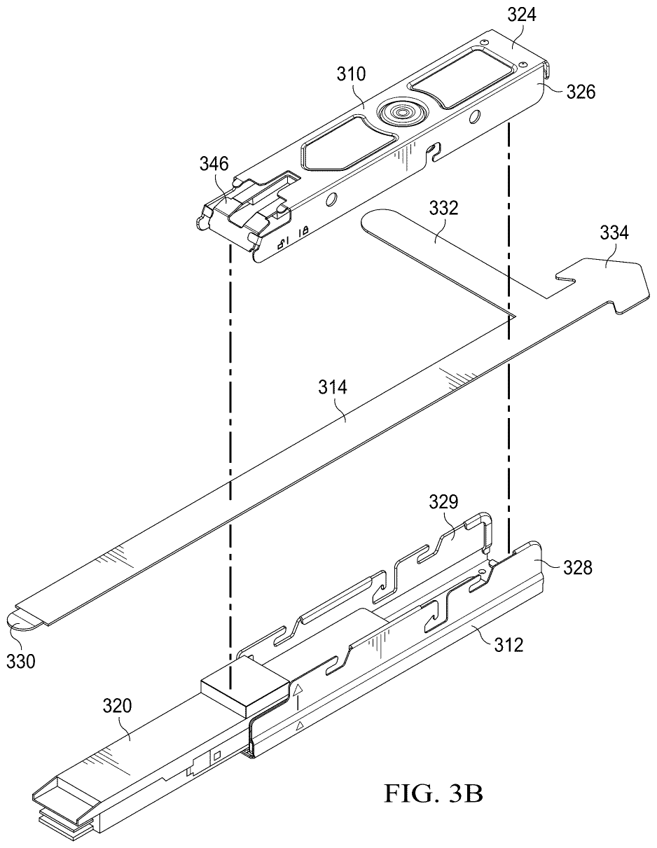

FIGS. 3A and 3B, generally referred to as FIG. 3, show views of a connector adapter component 300 of a connector adapter system. In certain embodiments, the connector adapter component 300 includes an adapter chassis 305. In certain embodiments, the adapter chassis includes a top cover 310, a bottom cover 312, a strap 314, or a combination thereof. In certain embodiments, the strap 314 fits within the adapter chassis 305. In certain embodiments, the strap 314 fits between to top cover 310 and the bottom cover 312.

In certain embodiments, a cable connector 320 fits within the adapter chassis 305. In certain embodiments, the cable connector 320 slides within the adapter chassis 305. In certain embodiments, the cable connector 320 slides within the adapter chassis 305 between an open location and a closed location. In certain embodiments, the cable connector 320 slides horizontally within the adapter chassis 305 between an open location (shown in FIGS. 3A and 3B) and a closed location. In certain embodiments, the cable connector 320 corresponds to an OSFP type cable connector.

In certain embodiments, the top cover 310 includes a top panel 322, a front side panel 324, a rear side panel (not shown in FIG. 3), or a combination thereof. In certain embodiments, the front side panel 324 extends substantially perpendicularly from the top panel 322. In certain embodiments, the rear side panel 324 extends substantially perpendicularly from the top panel 322. In certain embodiments, the bottom cover 312 includes a base panel 326, a front side panel 328, a rear side panel 329, or a combination thereof. In certain embodiments, the front side panel 328 extends substantially perpendicularly from the base panel 326. In certain embodiments, the rear side panel 329 extends substantially perpendicularly from the base panel 326. In certain embodiments, the top cover 310 and the bottom cover 312 are configured to removably attach to each other. In certain embodiments, the front panel 326 of the top cover 310 and the front panel 328 of the bottom cover 312 are configured to removably attach to each other. In certain embodiments, the rear panel of the top cover 310 and the rear panel 329 of the bottom cover 312 are configured to removably attach to each other.

In certain embodiments, the strap portion 314 includes a cable connector attachment portion 330, a cable securing extension 332 and a strap grasping portion 334. In certain embodiments, the cable connector attachment portion 330, the cable securing extension 332 and the strap grasping portion 334 are integrated into a single piece of material. In certain embodiments, the cable connector attachment portion 330 wraps around a release handle of the cable connector 320. In certain embodiments, the release handle includes a pull ring. In certain embodiments, the cable securing extension 332 wraps around a cable which is attached to the cable connector 320. In certain embodiments, the cable connector attachment portion 330, the cable securing extension 332, or a combination thereof, include respective loop and hook fasteners. In certain embodiments, the loop and hook fastener includes a Velcro type fastener. In certain embodiments, the strap portion 314 provides an extended release mechanism which facilitates disconnecting the cable connector 320 from the graphics processing unit when the graphics processing unit is an internally mounted component.

In certain embodiments, the top cover 310 includes a spring component 340 and a release latch 342. In certain embodiments, the release latch 342 is used to separate the top and bottom covers. In certain embodiments, the spring component 340 attached to the top cover provides a constraint to cable connectors 320 of various shapes. In certain embodiments, the bottom cover holds the cable connector 320 in place.

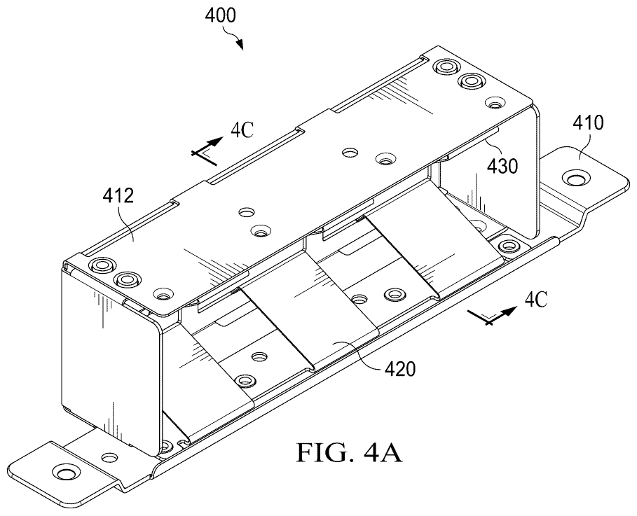

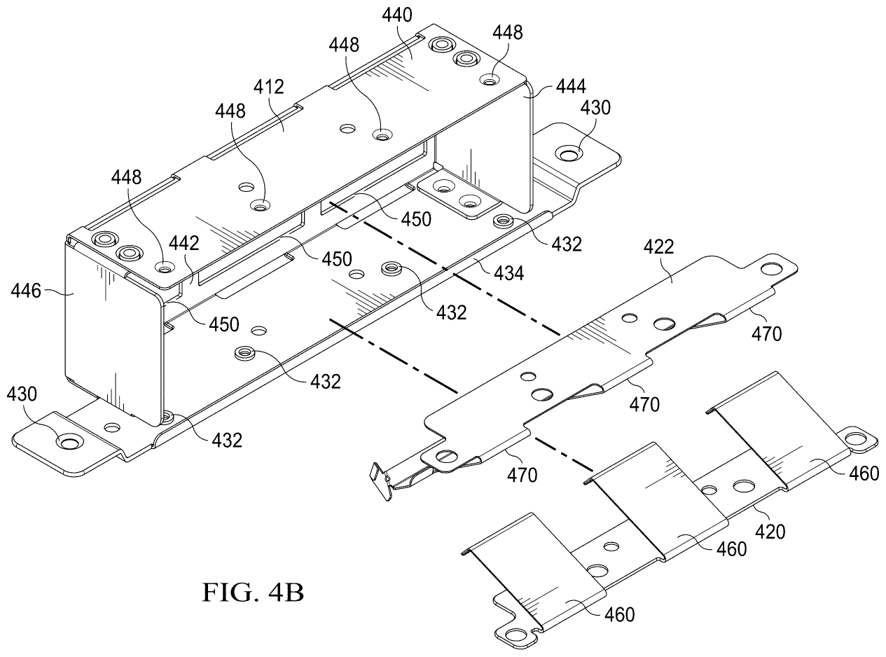

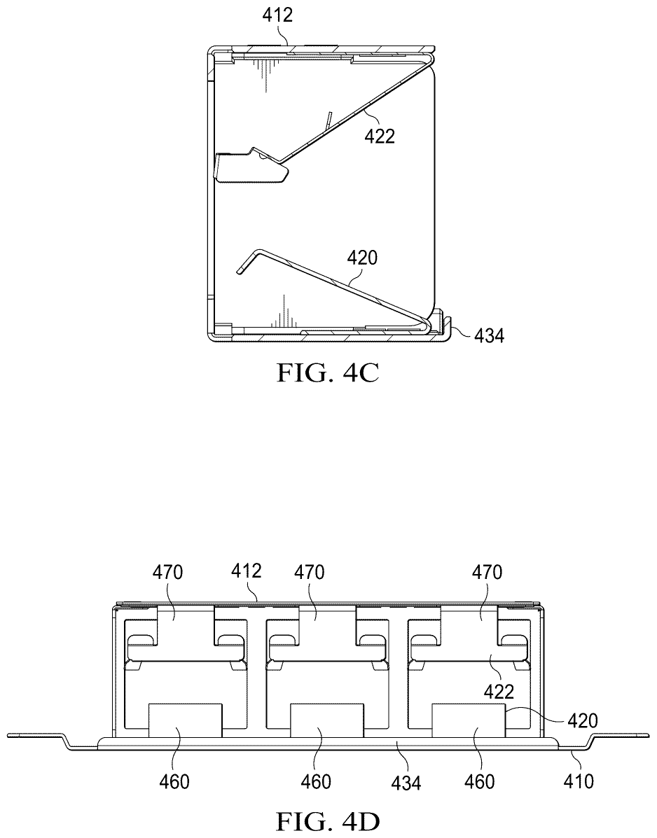

FIGS. 4A, 4B, 4C and 4D, generally referred to as FIG. 4, show views of a guiding structure 400 of a connector adapter system. In certain embodiments, the guiding structure 400 of the connector adapter system is positioned on a chassis side location. In certain embodiments, the guiding structure 400 constrains movements of a cable connector during installation of the cable connector.

In certain embodiments, the guiding structure 400 includes a base portion 410, a top housing 412, or a combination thereof. In certain embodiments, the top housing 412 is physically attached to the base portion 410. In certain embodiments, the guiding structure 400 includes a lower spring component 420, an upper spring component 422, or a combination thereof.

In certain embodiments, the base portion 410 defines one or more guiding structure attachment apertures 430. In certain embodiments, the guiding structure 400 is physically attached to a component chassis via the guiding structure attachment apertures 430. In certain embodiments, the base portion 410 includes one or more spring attachment projections 432. In certain embodiments, the lower spring component 420 is physically attached to the base portion via the spring attachment projections 432. In certain embodiments, the base portion 410 includes a front projecting edge 434. In certain embodiments, a front portion of the lower spring component 420 fits within the front projecting edge 434 when the lower spring component 420 is mounted to the base portion 410.

In certain embodiments, the top housing 412 includes a top panel 440, a rear panel 442, a right side panel 444, a left side panel 446, or a combination thereof. In certain embodiments, the rear panel 442 extends substantially perpendicularly from the top panel 322. In certain embodiments, the right side panel 444 extends substantially perpendicularly from the top panel 440. In certain embodiments, the left side panel 446 extends substantially perpendicularly from the top panel 440. In certain embodiments, the top housing 412 includes one or more spring attachment projections 448. In certain embodiments, the upper spring component 422 is physically attached to the top housing 412 via the spring attachment projections 448.

In certain embodiments, the rear panel 442 defines one or more guide apertures 450. In certain embodiments, each guide aperture 450 is position to guide a respective cable connector when the cable connector is being attached to a respective component receiving cable connector.

In certain embodiments, the lower spring component 420 includes one or more spring elements 460. In certain embodiments, the spring elements 460 are configured to apply an upward pressure to a cable connector as the cable connector is inserted into the guiding structure 400.

In certain embodiments, the upper spring component 422 includes one or more spring elements 470. In certain embodiments, the spring elements 470 are configured to apply a downward pressure to a cable connector as the cable connector is inserted into the guiding structure 400.

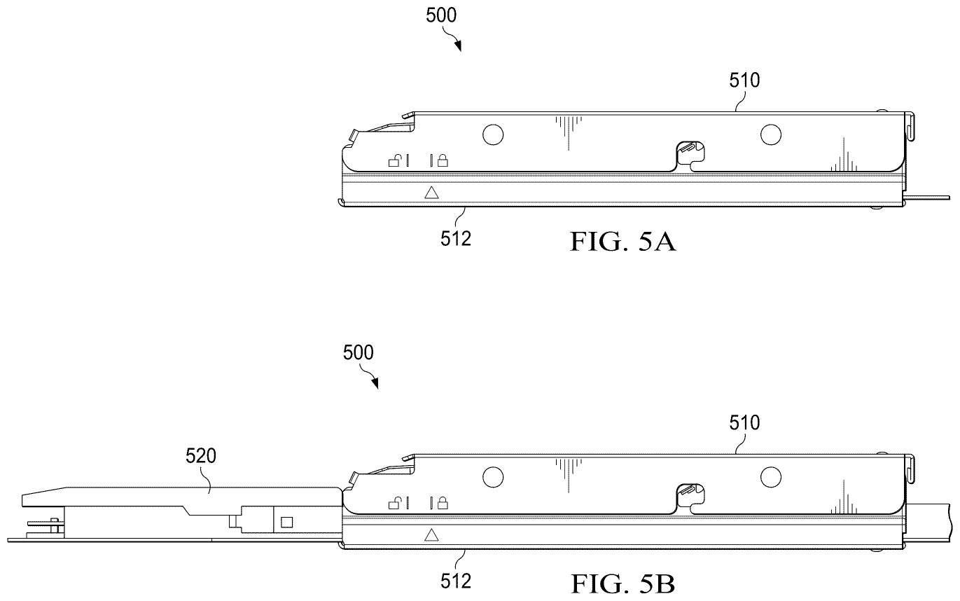

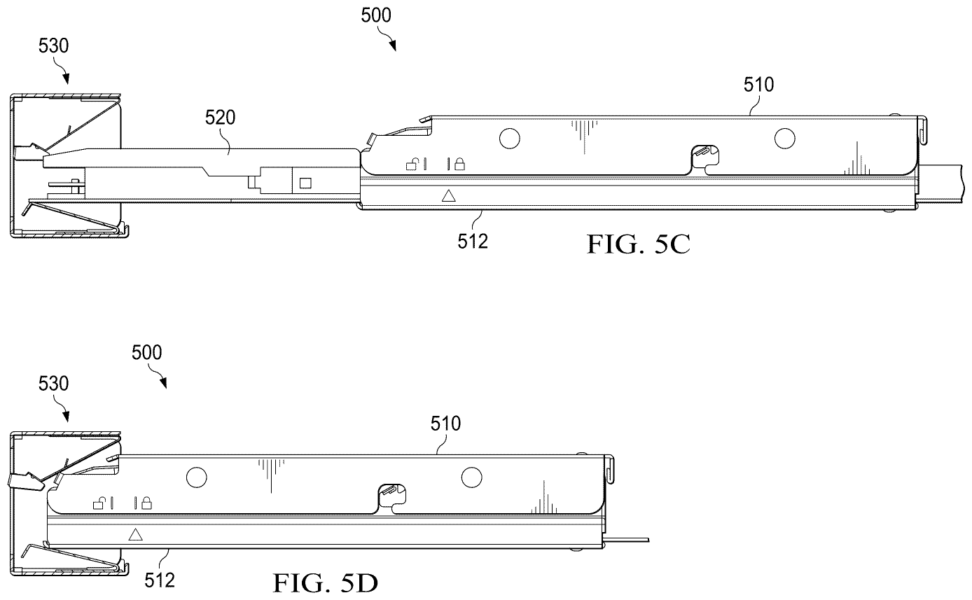

FIGS. 5A, 5B, 5C and 5D, generally referred to as FIG. 5, show side views of the operation of a connector adapter component of a connector adapter system. More specifically, FIG. 5A shows an initial position of the connector adapter component. FIG. 5B shows a cable connector installed within the connector adapter component. FIG. 5C shows the insertion of the cable connector into the guiding structure. FIG. 5D shows the connector adapter component fully inserted such that the cable connector is coupled with a receiving cable connector of the graphics processing unit module.

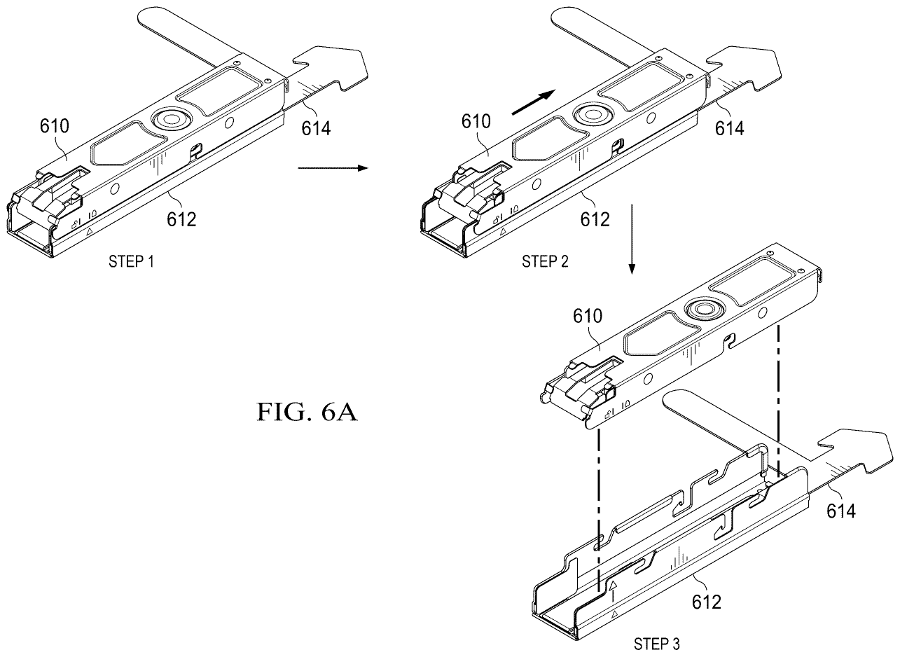

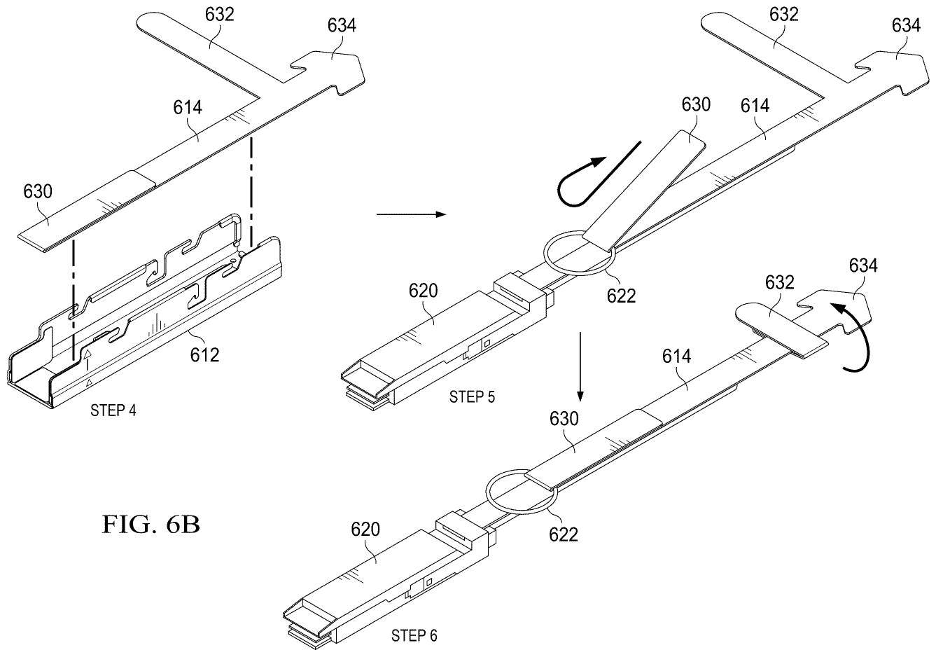

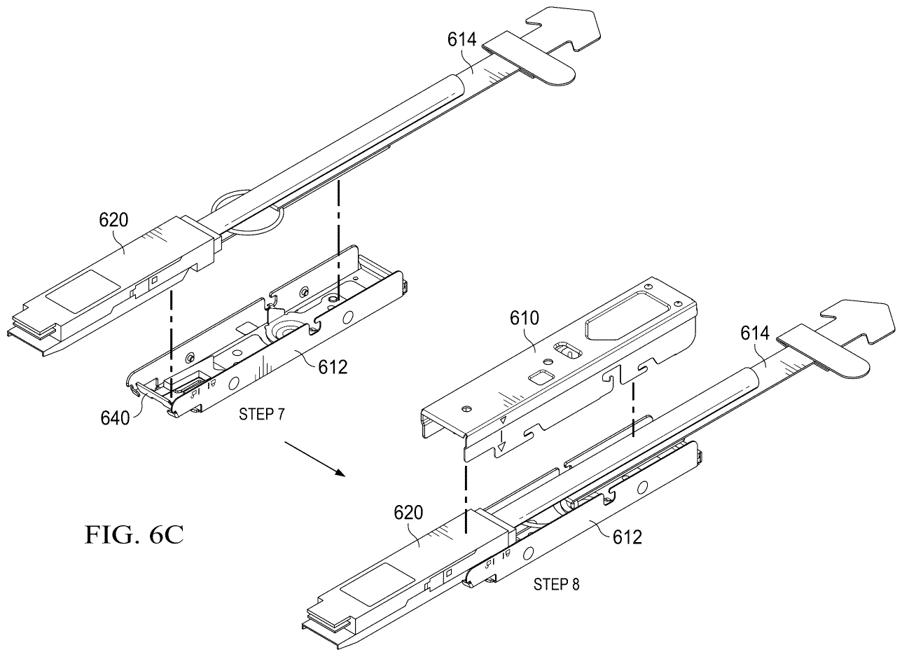

FIGS. 6A, 6B and 6C, generally referred to as FIG. 6, show operational views of assembly of a connector adapter component 600 of a connector adapter system.

More specifically, referring to FIG. 6A, assembly of the connector adapter component begins by separating the top cover 610 and the bottom cover 612 of the adapter chassis so that a cable connector can be associated with the connector adapter component 600. At step 1, the release latch 642 is actuated to release the connection of the top cover 610 to the bottom cover 612. Next at step 2, the top cover is slid horizontally to separate the top cover 610 and the bottom cover 612, which inlocks the latches holding top and bottom covers together. Next, at step 3, the top cover 610 is removed from the bottom cover 612.

Referring now to FIG. 6B assembly continues by connecting the strap 614 to the cable connector 620. More specifically, at step 4 the strap 614 is removed from the bottom cover 612. Next at step 5, the cable connector attachment portion 630 of the strap 614 is attached to the release handle of the cable connector 620. Next at step 6, the cable securing extension 332 of the strap 614 is wrapped around the cable to secure the strap 614 to the cable.

Referring now to FIG. 6C assembly continues by installing the cable connector and the strap 614 back into the adapter chassis. FIG. 6C shows a bottom view of the connector adapter component assembly. At step 7 the cable connector 620 is aligned with the spring component 640 of the top cover 610 and is inserted into the top cover 610. In certain embodiments, the cable connector includes a notch which is aligned with the spring component 640. Next at step 8, the bottom cover 612 is installed over the top cover 610 and is slid into place to physically attach the top cover 610 and the bottom cover 612 of the cover chassis.

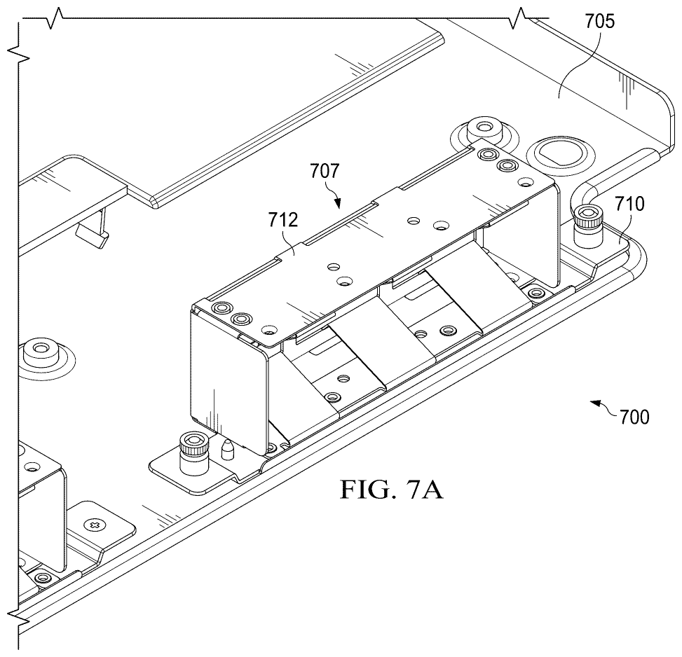

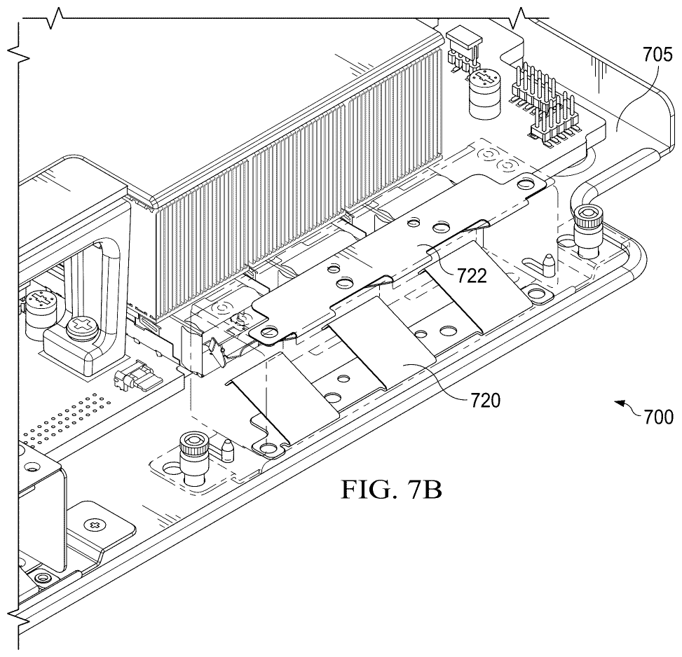

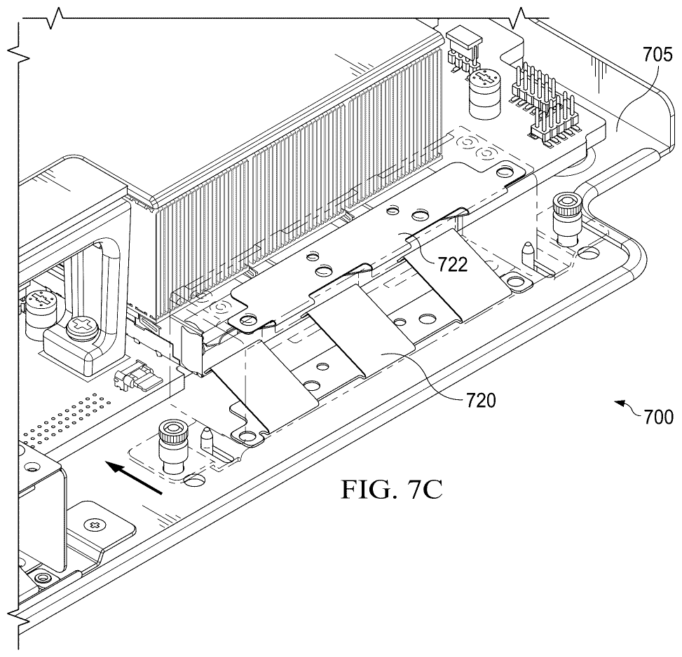

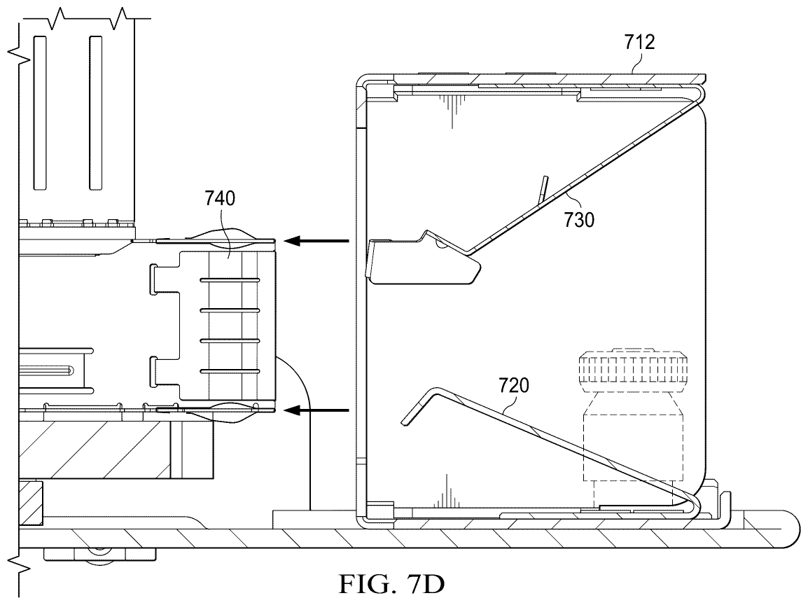

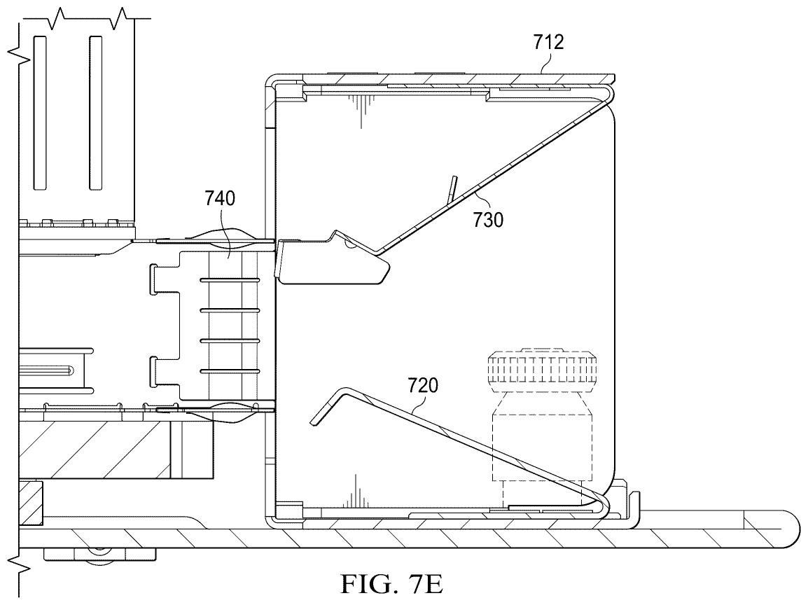

FIGS. 7A, 7B, 7C, 7D and 7E, generally referred to as FIG. 7, show operational views of a guide structure of a connector adapter system.

Guide structure is physically coupled to an edge of a component sled 705 such as a graphics processing unit sled. In certain embodiments, the component sled 705 provides a base housing via which various components of the component module are attached to provide the component module. A cable receiving connector 740 is an example of a component that is attached to the component sled. The guide structure 707 is attached via plunger locks inserted in apertures of a base portion 710 of the guide structure 707. The guide structure 707 is then slid (see e.g., FIG. 7D) to be contiguous with an edge of the cable receiving connector 740.

In certain embodiments, the rear wall of the guide structure 707 defines apertures which align with respective edges of each of a plurality of cable receiving connectors. When slid back, the apertures form a constraint edge around each of the respective plurality of cable receiving connectors. Once in position, the plungers are locked in place to physically couple the guide structure 707 to an edge of the component sled 705.

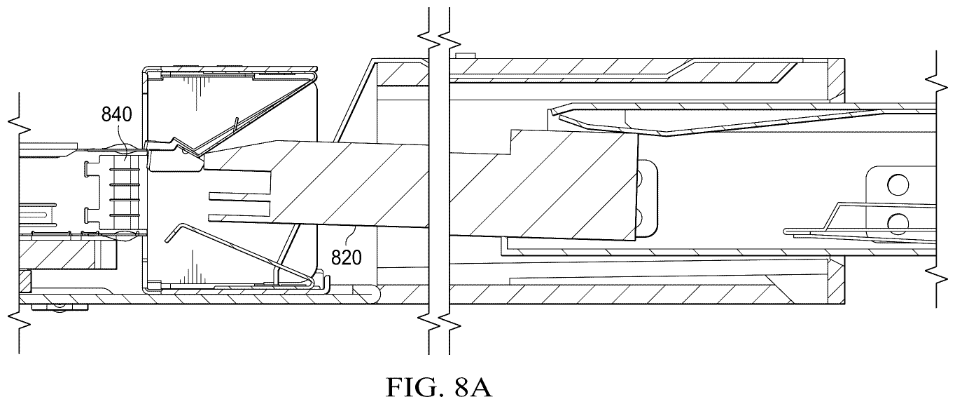

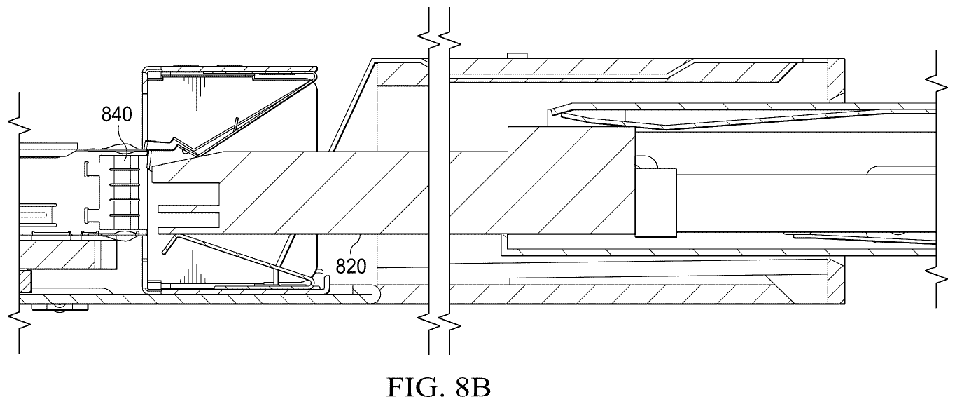

FIGS. 8A and 8B, generally referred to as FIG. 8, show operational side views of a connector adapter system.

In certain embodiments, the bottom spring component of the guide structure is stronger than the top spring component of the guide structure so that the plug of the cable connector is pressed down as the angled edge of the cable connector is inserted into the guide structure while maintaining alignment of the cable connector with the receiving connector of the graphics processing unit module.

In certain embodiments, the top spring of the guide structure is stronger than the spring of the adapter housing so that the that the plug of the cable connector is pushed downwardly as the angled edge of the cable connector is inserted into the guide structure while maintaining alignment of the cable connector with the receiving connector of the graphics processing unit module.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A connector adapter component of a connector adapter system of an information handling system, comprising:
an adapter chassis, the adapter chassis being configured to slidably mount a cable connector within the adapter chassis, the adapter chassis facilitating connection of the cable connector with an internally mounted component of the information handling system.

2. The connector adapter of claim 1, wherein:
the adapter chassis includes a top cover and a bottom cover, the top cover and the bottom cover being removable attached to allow mounting of the cable connection within the adapter chassis.

3. The connector adapter of claim 2, wherein:
the adapter chassis includes a spring component, the spring component providing a constraint to allow a plurality of cable connector shapes to be mounted within the adapter chassis.

4. The connector adapter of claim 1, further comprising:
a strap portion mounted within the adapter chassis, the strap portion being configured to be attached to the cable connection to provide an extended release function when disconnection the cable connector from the internally mounted component.

5. The connector adapter of claim 4, wherein:
the strap portion is attached to a release handle of the cable connector.

6. The connector adapter of claim 1, wherein:
the adapter chassis interacts with a guiding structure when the cable connector is attached to the internally mounted component.

7. A connector adapter system of an information handling system, comprising:
a connector adapter, the connector adapter comprising an adapter chassis, the adapter chassis being configured to slidably mount a cable connector within the adapter chassis, the adapter chassis facilitating connection of the cable connector with an internally mounted component of the information handling system.

8. The connector adapter system of claim 7, wherein:
the adapter chassis includes a top cover and a bottom cover, the top cover and the bottom cover being removable attached to allow mounting of the cable connection within the adapter chassis.

9. The connector adapter system of claim 8, wherein:
the adapter chassis includes a spring component, the spring component providing a constraint to allow a plurality of cable connector shapes to be mounted within the adapter chassis.

10. The connector adapter system of claim 7, further comprising:
a strap portion mounted within the adapter chassis, the strap portion being configured to be attached to the cable connection to provide an extended release function when disconnection the cable connector from the internally mounted component.

11. The connector adapter system of claim 10, wherein:
the strap portion is attached to a release handle of the cable connector.

12. The connector adapter system of claim 7, further comprising:
a guiding structure, the guiding structure interacting with the cable connector when the cable connector is attached to the internally mounted component.

13. A server type information handling system comprising:
a processor;
a data bus coupled to the processor;
a chassis,
an internally mounted component mounted within the chassis; and,
a connector adapter system, the connector adapter system comprising
a connector adapter, the connector adapter comprising an adapter chassis, the adapter chassis being configured to slidably mount a cable connector within the adapter chassis, the adapter chassis facilitating connection of the cable connector with the internally mounted component of the information handling system.

14. The system of claim 13, wherein:
the adapter chassis includes a top cover and a bottom cover, the top cover and the bottom cover being removable attached to allow mounting of the cable connection within the adapter chassis.

15. The system of claim 14, wherein:
the adapter chassis includes a spring component, the spring component providing a constraint to allow a plurality of cable connector shapes to be mounted within the adapter chassis.

16. The system of claim 13, wherein:
a strap portion mounted within the adapter chassis, the strap portion being configured to be attached to the cable connection to provide an extended release function when disconnection the cable connector from the internally mounted component.

17. The system of claim 16, wherein:
the strap portion is attached to a release handle of the cable connector.

18. The system of claim 13, wherein:
the connector adapter system includes a guiding structure, the guiding structure interacting with the cable connector when the cable connector is attached to the internally mounted component.
